(19) United States
(12) Patent Application Publication
(10) Pub. No.: US 2026/0313825 A1
(43) Pub. Date: Oct. 8, 2026

(54) CHASSIS AND SERVER

(71) Applicant: Fulian Precision Electronics (Tianjin) Co., LTD., Tianjin (CN)

(72) Inventors: YU-YONG HUANG, New Taipei (TW); YING-JIE HUANG, New Taipei (TW); YI-LIN LIU, New Taipei (TW)

(21) Appl. No.: 19/229,038

(22) Filed: Jun. 5, 2025

(30) Foreign Application Priority Data
Apr. 2, 2025 (CN) 202510412032.0

(51) Int. Cl. H05K 7/14

(52) U.S. Cl. CPC H05K 7/1492

(57) ABSTRACT

The present application relates to a chassis and a server. The chassis includes a shell and a carrier. The shell has a mounting space, and a connector is installed inside the mounting space. The carrier is installed in the mounting space and includes a primary body and a handle. The primary body is mounted on the shell, and the handle is rotatably installed on the primary body to be movable away from the connector, thereby facilitating the installation of the connector with other structures.

### FIELD

The subject matter relates to computer servers, and more particularly, to a chassis.

### BACKGROUND

In existing server designs, a carrier (tray) is usually arranged inside the chassis to carry components such as busbars. The carrier is typically equipped with a fixed handle for ease of operation. However, during the assembly process of the server, the busbar needs to be installed inside the chassis, and the busbar must be electrically connected to the connector inside the chassis via cables. The position and structure of the fixed handle often restrict the assembly space, making the installation of the busbar and the connection of the cables more difficult.

Therefore, there is room for improvement in the art.

### BRIEF DESCRIPTION OF THE DRAWINGS

FIG. 1 is a diagrammatic view of a structural composition of a serve according to an embodiment of the present application.

FIG. 2 is a diagrammatic view of a structural composition of a chassis according to an embodiment of the present application.

FIG. 3 is a diagrammatic view of a shell of the chassis shown in FIG. 1 to an embodiment of the present application.

FIG. 4 is a diagrammatic view of position A in FIG. 3.

FIG. 5 is a diagrammatic view of a carrier shown in FIG. 2, the handle is in an operating position according to an embodiment of the present application.

FIG. 6 is a diagrammatic view of the carrier shown in FIG. 2, when the handle is in a retracted position according to an embodiment of the present application.

FIG. 7 is a diagrammatic view of the carrier in the shell shown in FIG. 6 according to an embodiment of the present application.

FIG. 8 is an enlarged view of position B in FIG. 7.

### DETAILED DESCRIPTION

Implementations of the present technology will now be described, by way of example only, with reference to the attached figures.

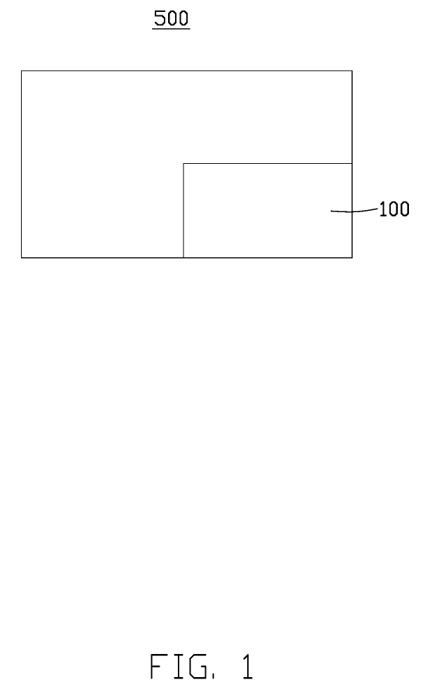

Referring to FIGS. 1, 2, and 3, an exemplary embodiment of the present application provides a chassis 100 and a server 500. The server 500 includes a connector 200, a cable 300, a busbar 400, and the chassis 100. The chassis 100 includes a shell 10 and a carrier 20. The carrier 20 is located inside the shell 10 and is configured to carry the busbar 400. The connector 200 is mounted on the shell 10, and the cable 300 connects the connector 200 and the busbar 400.

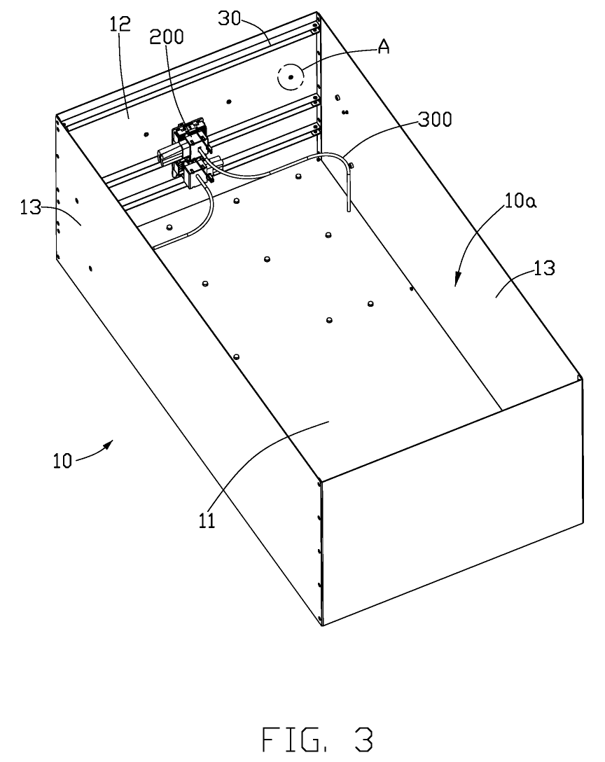

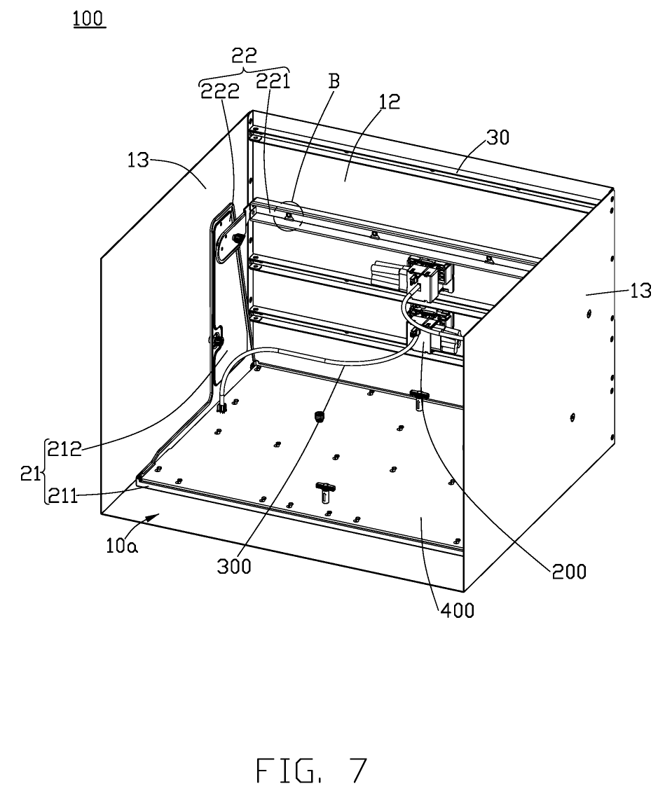

Referring to FIGS. 3, 5, and 7, the shell 10 includes a bottom wall 11, a first wall 12, and two second walls 13. The two second walls 13 are positioned on opposite sides of the first wall 12. The two second walls 13 and the first wall 12 surround the periphery of the bottom wall 11 to form a mounting space 10a.

In an embodiment, the first wall 12 and the two second walls 13 are perpendicularly connected to the bottom wall 11, and the two second walls 13 are perpendicularly connected to opposite sides of the first wall 12. The connector 200 connected with external components is mounted on the first wall 12 and located inside the mounting space 10a.

In another embodiment, the number of second wall 13 is one. Additionally, the first wall 12 is not perpendicular to the bottom wall 11, or the second wall 13 is not perpendicular to the bottom wall 11.

The carrier 20 is installed inside the mounting space 10a. The carrier 20 includes a primary body 21 and a handle 22, and the handle 22 is rotatably connected to the primary body 21. The primary body 21 includes a base 211 and two side walls 212 located on opposite sides of the base 211. The handle 22 includes a first section 221 and two second sections 222 located on opposite sides of the first section 221. The second section 222 is connected to the corresponding side wall 212 on the same side of the base 211.

In an embodiment, the number of the second sections 222 is one.

In an embodiment, the handle 22 rotates relative to the primary body 21 between a operating position and a retracted position to adjust position to provide clearance for operating other structures inside the shell 10.

When the handle 22 is in the retracted position, the first section 221 lies flush against the first wall 12 to minimize space occupation inside the shell 10 and enhance the structural strength of the first wall 12.

When the handle 22 rotates to the operating position, the first section 221 disengages from the first wall 12 and is positioned above the primary body 21, making it convenient for personnel to grip and lift the carrier 20. The rotatable handle 22 replaces the traditional fixed handle, improving assembly convenience.

The handle 22 can rotate relative to the primary body 21 between the operating position and the retracted position. When the handle 22 is in the operating position, the first section 221 presses against the first wall 12 to free up the mounting space 10a, preventing interference during the assembly of the busbar 400. Additionally, the first section 221 strengthens the structural integrity of the first wall 12.

When the handle 22 is in the operating position, the first section 221 moves away from the first wall 12 and is above the primary body 21 for convenient gripping when lifting the carrier 20. The rotatable handle 22 replaces the fixed handle in conventional designs, enhancing assembly efficiency.

In an embodiment, referring to FIGS. 3, 5, and 7, the base 211 remains parallel to the bottom wall 11, and the two side walls 212 are perpendicularly connected to the base 211, ensuring structural stability for the primary body 21. The two second sections 222 of the handle 22 are perpendicular to the first section 221. The two side walls 212, the two second sections 222, and the two second walls 13 of the shell 10 maintain a parallel relationship. The first section 221 remains parallel to the first wall 12. This precise arrangement of parallel and perpendicular relationships ensures an organized internal structure for the chassis 100.

The rotation angle of the handle 22 between the operating position and the retracted position is limited to 90 degrees. When the handle 22 rotates from the retracted position to the operating position, the first section 221 is above the primary body 21, facilitating gripping. When the handle 22 returns to the retracted position, the first section 221 fits against the first wall 12, optimizing space usage. The 90-degree rotation design ensures both operational simplicity and positional precision.

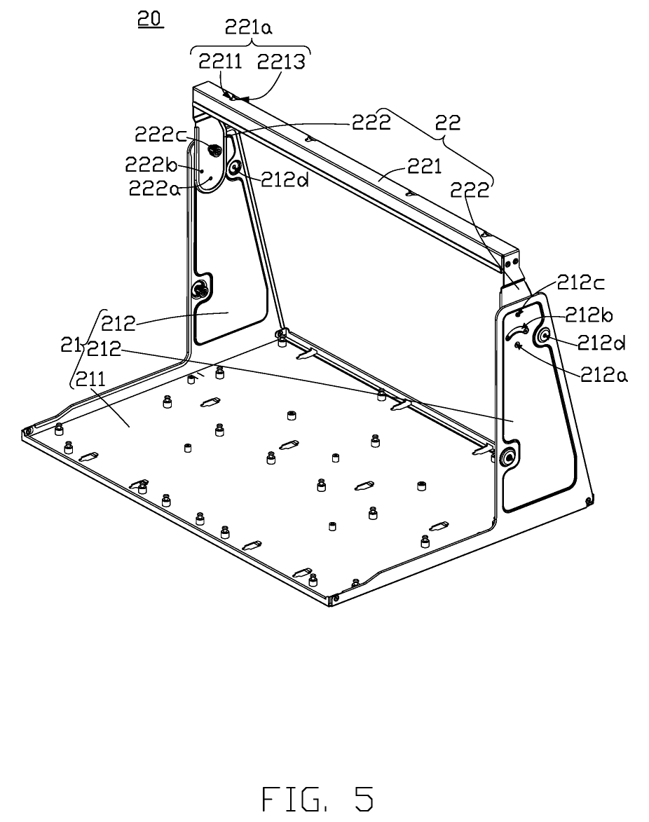

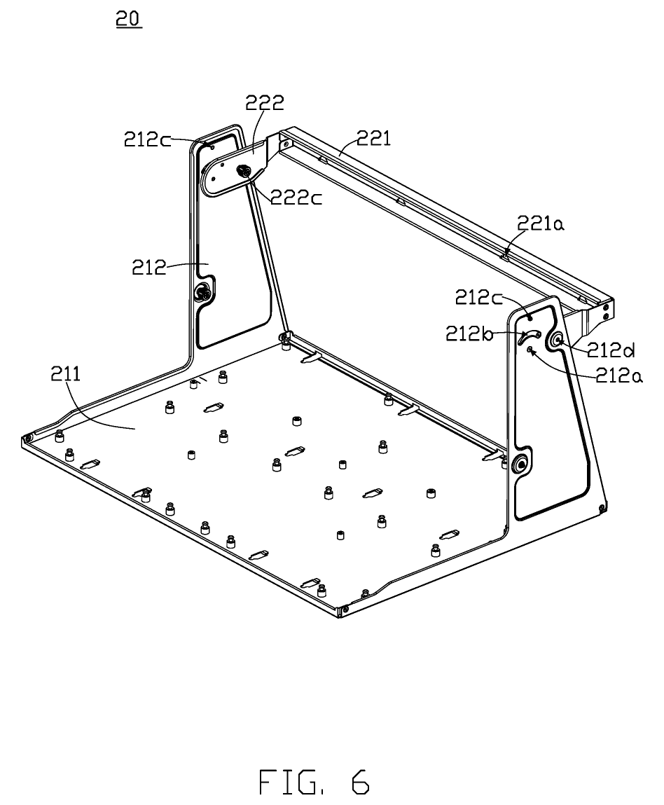

In an embodiment, referring to FIGS. 5-7, the side wall 212 is provided with a shaft hole 212a, the second section 222 is provided with a rotation shaft 222a. The rotation shaft 222a is inserted into the corresponding shaft hole 212a. Through this engagement between the rotation shaft 222a and the shaft hole 212a, the second section 222 could rotate relative to the side wall 212 around the rotation shaft 222a, enabling the entire handle 22 to transition from the retracted position to the operating position.

The handle 22 rotates smoothly while ensuring structural stability through its mechanical connections. The arrangement of the rotation shaft 222a and the shaft hole 212a allows the handle 22 to switch positions easily when needed, meeting various requirements for assembly and operation.

In an embodiment, referring to FIGS. 5-7, the side wall 212 is further provided with a curved groove 212b, and the curved groove 212b is centered around the shaft hole 212a in an arc-like distribution. The second section 222 is provided with a pin 222b, and the pin is inserted into the curved groove 212b and slide along the curved groove 212b. When the second section 222 rotates around the rotation shaft 222a, the sliding movement of the pin 222b inside the curved groove 212b guides the rotational direction of the second section 222, ensuring that the handle 22 remains stable during rotation without deviating from the intended trajectory. This coordinated design of the curved groove 212b and pin 222b further optimizes the rotational functionality of the handle 22, enhancing the overall reliability of the chassis 100.

Referring to FIGS. 5-7, the curvature of the curved groove212b is 90 degrees, corresponding to the right-angle rotational range between the "operating position" and the "retracted position" of the handle 22. Both ends of the curved groove 212b are provided with a groove wall. When the second section 222 rotates around the rotation shaft 222a, the pin 222b on each second section 222 is inserted into the corresponding curved groove 212b and slides along the arc-shaped path of the curved groove 212b until connecting the groove walls at either end of the curved groove 212b.

The groove walls at two ends of the curved groove 212b prevent further movement of the pin 222b, thereby serving as a limiting mechanism that ensures the handle 22 precisely stops at the intended position when reaching either the operating or retracted position. The design of the 90-degree arc and limiting function via the groove walls of the curved groove 212b enhances the smoothness and precision of the rotation of the handle 22, and improves the overall reliability of the chassis 100.

In an embodiment, referring to FIGS. 5-7, the side wall 212 is provided with a first positioning hole 212c, and the second section 222 is provided with a positioning member 222c. When the handle 22 is rotated to the operating position, the positioning member 222c aligns precisely with the first positioning hole 212c on the corresponding side wall 212, and the positioning member 222c could be inserted into the first positioning hole 212c, securely locking the handle 22 in the operating position and preventing unintended rotation or loosening during operation, enhancing operational safety and ensuring a stable grip when lifting the carrier 20, further improving the practicality of the chassis 100.

The positioning member 222c is implemented as a thumb screw, which includes a threaded shaft and a manually rotatable knob. When the handle 22 is rotated to the operating position, the thumb screw aligns with the first positioning hole 212c on the corresponding side wall 212. The user can manually rotate the knob to thread the shaft into the first positioning hole 212c, firmly securing the handle 22 in the operating position and preventing unintended movement, eliminating the need for additional tools while providing reliable locking force, enhancing both safety and convenience, and ensuring a stable grip when lifting the carrier 20 and further improving the practicality of the chassis 100.

In an embodiment, referring to FIGS. 5-7, the side wall 212 is further provided with a second positioning hole 212d. When the handle 22 is rotated to the retracted position, the positioning member 222c on the second section 222 aligns with the second positioning hole 212d. The positioning member 222c is inserted into the second positioning hole 212d, securely fixing the handle 22 in the retracted position and preventing accidental movement in this state. This dual-positioning-hole design of first positioning hole 212c and second positioning hole 212d ensures reliable locking at two critical positions, further enhancing the stability of the chassis 100.

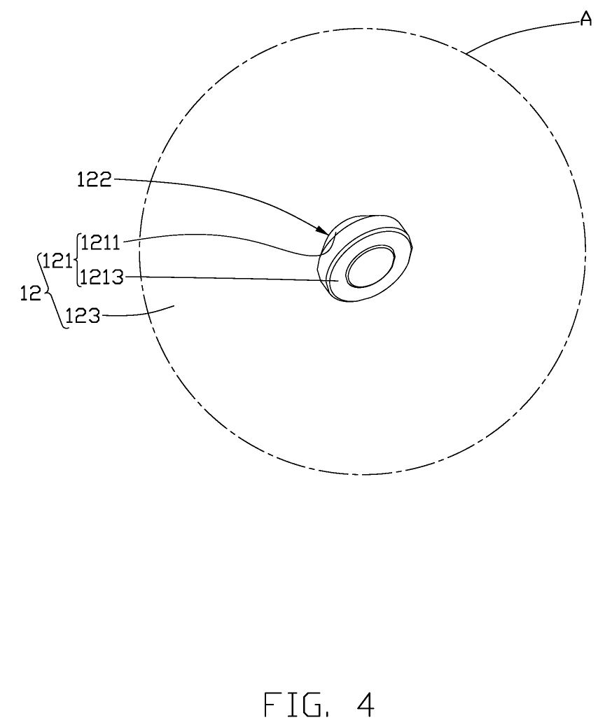

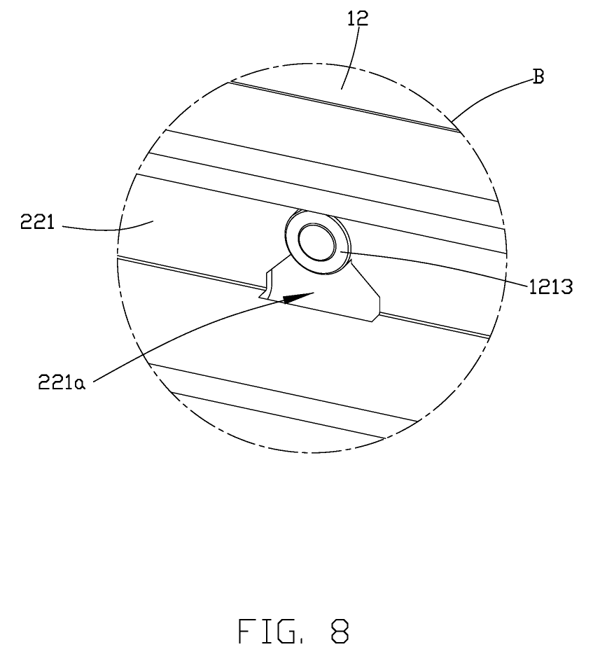

In an embodiment, referring to FIGS. 4, 7, and 8, the first section 221 is provided with a multiple of sockets 221a, and the multiple of the sockets 221a are arranged alternately along the length direction of first section221. The socket 221a runs through the side of the first section 221 facing the first wall 12.

The first wall 12 comprises a multiple of spaced bosses 121. When the handle 22 is rotated to the retracted position, the first section 221 closely adheres to the first wall 12, with each boss 121 precisely inserted into the corresponding socket 221a, securely positioning the first section 221 against the first wall 12, and preventing displacement of the first section 221 in the retracted position while reinforcing the overall connection strength between the handle 22 and the shell 10.

In an embodiment, referring to FIGS. 4, 7, and 8, the socket 221a features a flared opening to facilitate smooth insertion of the boss 121. The first wall 12 further includes a main body 123. The boss 121 includes a connection portion 1211 and a stop block 1213. The connection portion 1211 is attached to the main body 123, and the stop block 1213 connects to the connection portion 1211 and is spaced apart from the main body 123, forming a limiting groove 122 between the main body 123 and the stop block 1213. The limiting groove 122 accommodates the peripheral edge of the socket 221a, and the stop block 1213 blocks the side of the peripheral edge of the socket 221a away from the main body 123.

In an embodiment, the socket 221a comprises a first region 2211 and a second region 2213. The first region 2211 has a larger opening than the second region 2213. The first region 2211 and the second region 2213 are sequentially arranged along the circumferential direction in which the handle rotates toward the first wall 12. The stop block 1213 is configured to pass through the first region 2211 and positioned on a side of the handle 22 facing away from the first wall 12, while the connection portion 1211 enters the second region 2213.

When the boss 121 is inserted into the socket 221a, the edge of the socket 221a can be embedded into the limiting groove 122, thereby effectively restricting the movement of the first section 221, further preventing the first section 221 from loosening or disengaging in the retracted position, and enhancing the structural stability.

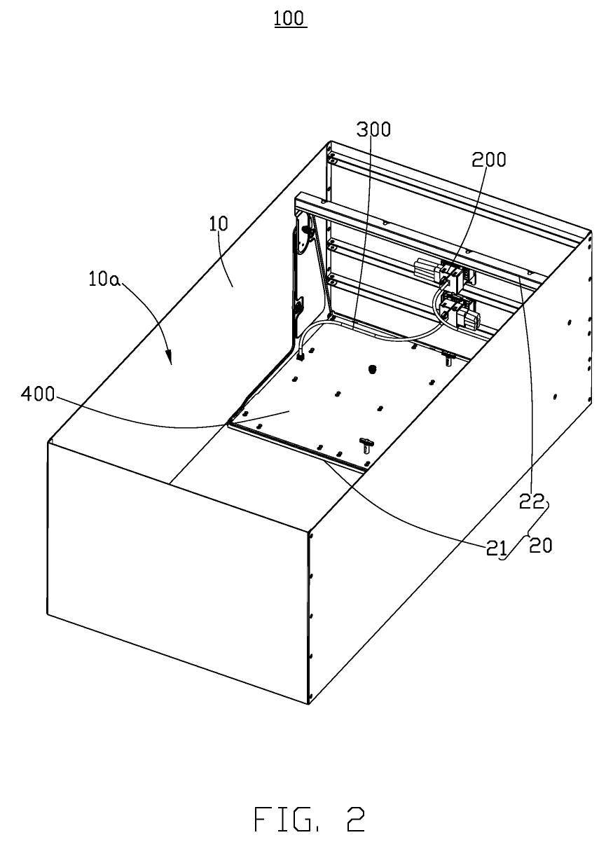

In an embodiment, referring to FIGS. 2, 3, and 7, the inner side of the first wall 12 is provided with multiple parallel reinforcement ribs 30, and both ends of the reinforcement rib 30 is connected to the two opposite second walls 13, forming a support framework that increases the rigidity and deformation resistance of the first wall 12. When the handle 22 is in the retracted position, the first section 221 adheres to the first wall 12, reinforcing structure with these reinforcement ribs 30. The first section 221 not only serves as a stowage feature but also functions as an additional reinforcement rib 30, further improving the overall strength of the first wall 12. This design capitalizes on the positional characteristics of the handle 22 in the stowed state, combining its function with the reinforcement of the first wall 12 to optimize the structural performance of the chassis 100. Optionally, the reinforcement ribs 30 can also support the connector 200, improving the stability of the connector 200.

The terms used in the present application, such as “first” and “second”, do not intended to indicate any order, quantity, or importance of related components, but are only used for differentiation between the related components.

As used in the present application, the term “a” or “one” do not intended to limit the quantity of the related object, but to indicate the existence of at least one related object.

In the present application, the terms indicating direction or position, such as “top”, “bottom”, “side”, “longitudinal”, “transverse”, “middle”, “center, “outer”, “inner”, “horizontal”, “vertical”, “left”, “right”, “upper”, and “lower”, refers to a relative position rather than an absolute position.

The terms used in the present application, such as “substantially”, “whole”, “approximate”, and “similar”, are intended to indicate that the object has related characteristics but allow for certain deviations. The deviation may depend on a specific background. For example, the dimension of deviation may depend on a specific background, including but not limited to national standards for dimensional tolerances.

What is claimed is:

1. A chassis comprising:
a shell defining a mounting space configured for installing a connector; and
a carrier arranged in the mounting space, the carrier comprising:
a primary body arranged on a shell; and
a handle rotatably mounted on the primary body, wherein the handle is movable away from the connector when the handle is rotated relative to the primary body.

2. The chassis to claim 1, wherein the shell comprises a bottom wall and a first wall located on a side of the bottom wall;
the first wall is configured to install the connector, the handle is configured to be rotatable to a retracted position, when the handle is at the retracted position, the handle is in contact with the first wall and configured to remain in the retracted position.

3. The chassis to claim 2, wherein the handle comprises at least one socket, the first wall comprises at least one boss, when the handle is rotated to the retracted position, the at least one boss is inserted into the at least one socket and abuts against a side of the handle facing away from the first wall.

4. The chassis to claim 3, wherein the first wall further comprises a main body, the at least one boss comprises a connection portion and a stop block;
the connection portion is connected to the main body, the stop block is connected to the connection portion and spaced apart from the main body, a limiting groove is formed between the main body and the connection portion;
the limiting groove is configured to accommodate a peripheral edge of the at least one socket, and the stop block abuts against a side of the peripheral edge of the at least one socket facing away from the main body.

5. The chassis to claim 4, wherein the at least one socket comprises a first region and a second region, and an opening of the first region is larger than an opening of the second region;
the second region and the first region are sequentially arranged along a circumferential direction, the handle rotates toward the first wall in the circumferential direction;
the stop block is configured to extend through the first region and is positioned on a side of the handle facing away from the first wall, and the connection portion extends into the second region.

6. The chassis to claim 4, wherein the primary body comprises a base and at least one side wall, and the base is configured to be installed inside the shell, the side wall is connected to one side of the base;
the handle comprises a first section and at least one second section, and the first section is arranged on one side of the second section;
the at least one second section is rotatably connected to the at least one side wall, the at least one second section of the handle is rotatable relative to the primary body between the retracted position and an operating position;
the first section is configured to abut the first wall when the handle is in the retracted position, and the first section is disengageable from the first wall for holding when the handle is in the operating position.

7. The chassis to claim 6, wherein one of the at least one side wall or the at least one second section comprises a shaft hole, and another one of the at least one side wall or the at least one second section comprises a rotation shaft, the rotation shaft is inserted into the shaft hole.

8. The chassis to claim 7, wherein one of the at least one side wall or the at least one second section further comprises a curved groove, and another one of the at least one side wall or the at least one second section further comprises a pin;
the curved groove is centered on the shaft hole, the pin is inserted into the curved groove and is configured to slide along the curved groove.

9. The chassis to claim 6, wherein the at least one side wall defines a first positioning hole, and the at least one second section comprises a positioning member;
the positioning member is insertable into the first positioning hole, when the handle is in the operating position, the positioning member is inserted into the first positioning hole to position the handle.

10. The chassis to claim 9, wherein the at least one side wall defines a second positioning hole, and the at least one second section comprises a positioning member;
the positioning member is insertable into the second positioning hole, when the handle is in the retracted position, the positioning member is inserted into the second positioning hole to position the handle.

11. The chassis to claim 6, wherein a number of the at least one side walls is two, and a number of the at least one second sections is two;
the two side walls are connected at intervals on the same side of the base, and the two second sections are connected at intervals on a same side of the first section; each the two second sections is rotatably connected to a corresponding side wall of the two side walls.

12. The chassis to claim 6, wherein the first section is parallel to the first wall, and a rotation angle of the handle from the operating position to the retracted position is a right angle.

13. The chassis to claim 6, wherein the first wall is perpendicular to the bottom wall, the side wall is perpendicular to the base, and the at least one second section is perpendicular to the first section.

14. The chassis to claim 6, wherein the shell further comprises two second walls connected on the side of the bottom wall having the first wall, and the two second walls locate on opposite sides of the first wall;
the first wall is provided with a plurality of reinforcement ribs arranged in parallel, and each the plurality of reinforcement ribs is connected at both ends to the two second walls located on opposite sides of the first wall, and the plurality of reinforcement ribs and the boss are arranged at intervals.

15. The chassis to claim 14, wherein the side wall is connected to the two second walls.

16. The chassis to claim 3, wherein a number of the at least one socket is multiple, and a number of the at least one boss is multiple;
the multiple sockets are arranged at intervals along a rotation axis direction of the handle; the multiple bosses are arranged at intervals along the rotation axis direction of the handle, and each the multiple bosses is configured to be inserted into a corresponding socket of the multiple sockets.

17. A chassis comprising:
a shell comprising a bottom wall and a first wall disposed on one side of the bottom wall, the first wall comprising a boss and configured to mounted a connector;
a carrier comprising a primary body and a handle, wherein the handle comprises a socket, the handle is rotatable relative to the primary body to a retracted position to abut against the first wall, and the boss is inserted into the socket and stopped on a side of the handle facing away from the first wall.

18. The chassis to claim 17, wherein the first wall further comprises a main body, the boss comprises a connection portion and a stop block;
the connection portion is connected to the main body, the stop block is connected to the connection portion and spaced apart from the main body, a limiting groove is formed between the main body and the stop block;
the limiting groove is configured to accommodate an outer peripheral edge of the socket, and the stop block is blocked on a side of the outer peripheral edge of the socket facing away from the main body.

19. The chassis to claim 17, wherein the socket comprises a first region and a second region, and an opening of the first region is larger than an opening of the second region;
the second region and the first region are sequentially arranged along a circumferential direction, the handle rotates toward the first wall in the circumferential direction;
the stop block is configured to extend through the first region and is positioned on a side of the handle facing away from the first wall, and the connection portion extends into the second region.

20. A server, comprising:
a connector;
a busbar;
a cable; and
a chassis comprising:
a shell defining a mounting space configured for installing a connector; and
a carrier arranged in the mounting space, the carrier comprising:
a primary body arranged on a shell; and
a handle rotatably mounted on the primary body, wherein the handle is movable away from the connector when the handle is rotated relative to the primary body;
wherein the connector is arranged on a first wall, the busbar is arranged on the carrier, and two ends of the cable are plugged into the busbar and the connector to electrically connect the busbar and the connector.
